(19) United States
(12) Patent Application Publication
(10) Pub. No.: US 2026/0371611 A1
(43) Pub. Date: Nov. 19, 2026

(54) RESISTANCE CHANGE MEMORY DEVICE

(71) Applicant: SK hynix Inc., Icheon-si (KR)

(72) Inventor: Young Jae KWON, Icheon-si (KR)

(21) Appl. No.: 19/679,070

(22) Filed: May 15, 2026

(30) Foreign Application Priority Data
May 15, 2025 (KR) 10-2025-0063473

(51) Int. Cl. H10B 63/00; G11C 5/06; H10N 70/00

(52) U.S. Cl. CPC H10B 63/845; G11C 5/063; H10B 63/20; H10N 70/841; H10N 70/883

(57) ABSTRACT

A resistive memory device includes: a variable resistance layer disposed over an upper portion of a first electrode; a second electrode disposed over an upper portion of the variable resistance layer; a first resistance layer contacting the second electrode; an insulation layer surrounding side surfaces of the variable resistance layer and the second electrode; and a second resistance layer surrounding the insulation layer and contacting the first electrode.

### CROSS-REFERENCE TO RELATED APPLICATION

This patent document claims the priority under 35 U.S.C. §119(a) and the benefits of Korean patent application No. 10-2025-0063473, filed on May 15, 2025, the disclosure of which is incorporated herein by reference in its entirety as part of the disclosure of this patent document.

### TECHNICAL FIELD

The technology and implementations disclosed in this patent document generally relate to a resistance change memory device, and more particularly to a resistance change memory device including at least one memory cell having a parallel resistor and a series resistor.

### BACKGROUND

A resistance change memory may include a variable resistance layer in which internal resistance variably changes in response to an externally supplied voltage or current. The resistance change memory may refer to a nonvolatile memory capable of storing multi-level logic information as the changed resistance is nonvolatilely recorded within the variable resistance layer.

A variable resistance material included in the resistance change memory device is reversibly switchable, and each resistance change memory device may utilize the physical characteristics of a low resistance state (LRS) and a high resistance state (HRS) of the variable resistance material as data states.

The resistance change memory is advantageous not only in terms of fast switching capability and low-power driving capability, but also in terms of scaling due to a simple cell configuration thereof.

### SUMMARY

Various embodiments of the present disclosure relate to a resistive memory device having excellent data retention capability and long lifespan by improving the durability thereof.

In accordance with an embodiment of the present disclosure, a resistive memory device may include: a variable resistance layer disposed over an upper portion of a first electrode; a second electrode disposed over an upper portion of the variable resistance layer; a first resistance layer disposed to contact the second electrode; an insulation layer disposed to surround side surfaces of the variable resistance layer and the second electrode; and a second resistance layer disposed to surround the insulation layer and contact the first electrode.

In some implementations, the resistive memory device may further include: a second electrode contact disposed to commonly contact the first resistance layer and the second resistance layer.

In some implementations, the variable resistance layer may include a conductive filament comprising oxygen vacancies.

In some implementations, the variable resistance layer may include a metal oxide layer and an oxygen vacancy reservoir layer.

In some implementations, the metal oxide layer may include an oxide of at least one of tantalum (Ta), scandium (Sc), yttrium (Y), titanium (Ti), zirconium (Zr), vanadium (V), chromium (Cr), niobium (Nb), osmium (Os), manganese (Mn), iron (Fe), nickel (Ni), copper (Cu), silver (Ag), zinc (Zn), hafnium (Hf), or tungsten (W).

In some implementations, the metal oxide layer may include a metal oxide having a higher oxidation potential energy than that of the oxygen vacancy reservoir layer.

In some implementations, the oxygen vacancy reservoir layer may include a metal or an oxide of the metal that is at least one of tantalum (Ta), titanium (Ti), zirconium (Zr), vanadium (V), tungsten (W), or ruthenium (Ru).

In some implementations, the first electrode and the second electrode may include a non-reactive conductive material.

In some implementations, the variable resistance layer may have an activation resistance value when a conductive filament is present and a deactivation resistance value when the conductive filament is not present or electrically disconnected.

In some implementations, a resistance value of the first resistance layer may be greater than the activation resistance value of the variable resistance layer and less than the deactivation resistance value of the variable resistance layer.

In some implementations, the resistive memory device may further include a resistance value of the first resistance layer being less than a resistance value of the second resistance layer.

In some implementations, the resistive memory device may further include: a resistance isolation layer disposed over an upper portion of the second electrode and surrounding side surfaces of the first resistance layer.

In some implementations, the resistive memory device may further include: a second electrode contact disposed to contact the first resistance layer, wherein the second resistance layer is in contact with side surfaces of the second electrode contact.

In some implementations, the resistive memory device may further include: a first electrode contact disposed to contact the first electrode; a second electrode contact disposed to contact the first resistance layer; at least one bitline contacting the first electrode contact and extending in a first direction; and at least one wordline contacting the second electrode contact and extending in a second direction.

In some implementations, the first resistance layer may include a plurality of material layers having different resistance values.

In some implementations, the resistive memory device may further include: the first resistance layer includes an area of one surface contacting the second electrode that is smaller in width than an area of another surface facing or opposite to the area of the one surface.

In accordance with another embodiment of the present disclosure, a resistive memory device may include: a first electrode connected to a first electrode contact; a variable resistance layer connected in series to the first electrode; a second electrode connected in series to the variable resistance layer; a first resistance layer connected in series to the second electrode; a second resistance layer connected to the first electrode, and connected in parallel to the variable resistance layer, the second electrode, and the first resistance layer; and a second electrode contact connected to the first resistance layer and the second resistance layer.

In some implementations, the resistive memory device may further include: the first electrode contact is connected to a bitline; and the second electrode contact is connected to a wordline.

In some implementations, the resistive memory device may further include: an insulation layer disposed on side surfaces of the variable resistance layer, the second electrode, the first resistance layer, and the second resistance layer, wherein the insulation layer electrically isolates the variable resistance layer, the second electrode, the first resistance layer, and the second resistance layer from one another.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a schematic diagram illustrating a memory cell array according to an embodiment of the present disclosure.

FIG. 2 is a cross-sectional view illustrating a resistive memory cell according to an embodiment of the present disclosure.

FIGS. 3A and 3B are cross-sectional views illustrating methods for operating the resistive memory cell according to an embodiment of the present disclosure.

FIGS. 4A and 4B are equivalent circuit diagrams illustrating the resistive memory cell according to an embodiment of the present disclosure.

FIG. 5 is a cross-sectional view illustrating a resistive memory device according to another embodiment of the present disclosure.

FIG. 6 is a cross-sectional view illustrating a resistive memory device according to still another embodiment of the present disclosure.

### DETAILED DESCRIPTION

This patent document provides implementations and examples of a resistance change memory device, and more particularly to a resistance change memory device including at least one memory cell having a parallel resistor and a series resistor that may be used in configurations to substantially address one or more technical or engineering issues and to mitigate limitations or disadvantages encountered in other memory devices. Some implementations of the present disclosure relate to a resistive memory device having excellent data retention capability and long lifespan by improving the durability thereof. In recognition of the issues above, the present disclosure may provide the resistive memory cell that includes a series resistor and a parallel resistor, and adjusts resistance values of the series and parallel resistors, so that uniformity between the activation resistance and deactivation resistance during switching cycles can be maintained. The present disclosure may provide the resistive memory cell that can prevent durability degradation caused by repeated switching cycles by adjusting the resistance values of the series and parallel resistors, thereby improving the reliability of the switching mechanism.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

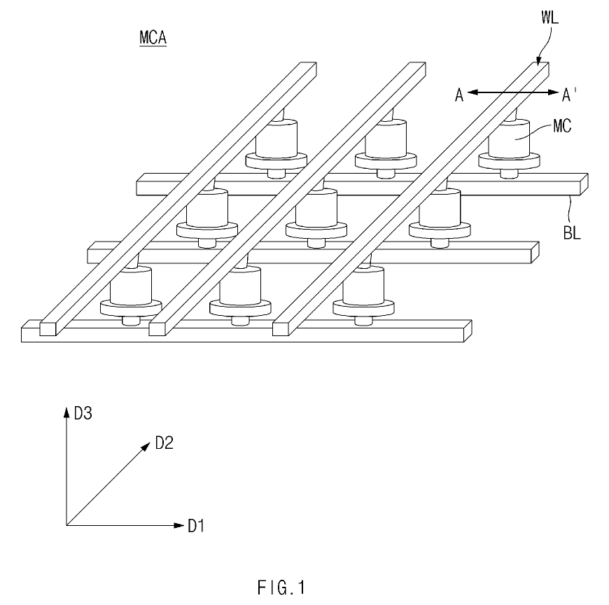

FIG. 1 is a schematic diagram illustrating a memory cell array (MCA) according to an embodiment of the present disclosure.

Referring to FIG. 1, a memory cell array (MCA) included in a resistive memory device may include a plurality of resistive memory cells (MCs) repeatedly arranged in a first direction (D1) and a second direction (D2). Here, the first direction (D1) may be a row direction, and the second direction (D2) may be a column direction.

In addition, the memory cell array (MCA) may include a plurality of bitlines (BL) extending in the first direction (D1), and a plurality of wordlines (WL) extending in the second direction (D2).

Each of the resistive memory cells (MCs) may contact the bitline (BL) and the wordline (WL). The plurality of resistive memory cells (MCs) repeatedly arranged in the first direction (D1) may commonly contact a single bitline (BL), and the plurality of resistive memory cells (MCs) repeatedly arranged in the second direction (D2) may commonly contact a single wordline (WL).

In the memory cell array (MCA), each resistive memory cell (MC) may be disposed at an intersection of one wordline (WL) and one bitline (BL).

The read and write operations of any resistive memory cell (MC) selected from among the memory cell array (MCA) may be performed by activating the wordline (WL) and bitline (BL) coupled to the selected resistive memory cell (MC).

For example, the resistive memory device including the memory cell array (MCA) may further include a wordline control circuit (not shown).

The wordline control circuit (not shown) may activate an arbitrary wordline (WL) to select an arbitrary resistive memory cell (MC) among the resistive memory cells (MC) coupled to the wordline (WL).

The resistive memory device may include a bitline control circuit (not shown) coupled to the resistive memory cells (MC) through each bitline (BL).

The bitline control circuit may activate the bitline (BL), and may read out data from the selected resistive memory cell (MC) among the resistive memory cells (MC) connected to the bitline (BL).

The wordline control circuit may activate the corresponding wordline (WL) coupled to the selected resistive memory cell (MC), and the bitline control circuit may activate the bitline (BL) coupled to the selected resistive memory cell (MC), so that each of the wordline control circuit and the bitline control circuit can access the resistive memory cell (MC).

During the write operation, the wordline control circuit may write data to the selected resistive memory cell (MC) by applying a predetermined voltage to the selected wordline (WL).

The resistive memory cells (MC) may store logic values based on a change in resistance value of a variable resistance layer (not shown) included in each resistive memory cell (MC).

In some embodiments, when the variable resistance layer can have multiple resistance values, storage of multi-bit logic values is also possible.

The change in the resistance value of the variable resistance layer may be detected through the read operation.

During the read operation, the wordline control circuit may apply a predetermined voltage to the selected wordline (WL), and the bitline control circuit may detect a current from the selected bitline (BL).

The bitline control circuit may detect a logic value of the selected resistive memory cell (MC) based on the magnitude of the detected current, and may output the resulting value to the outside.

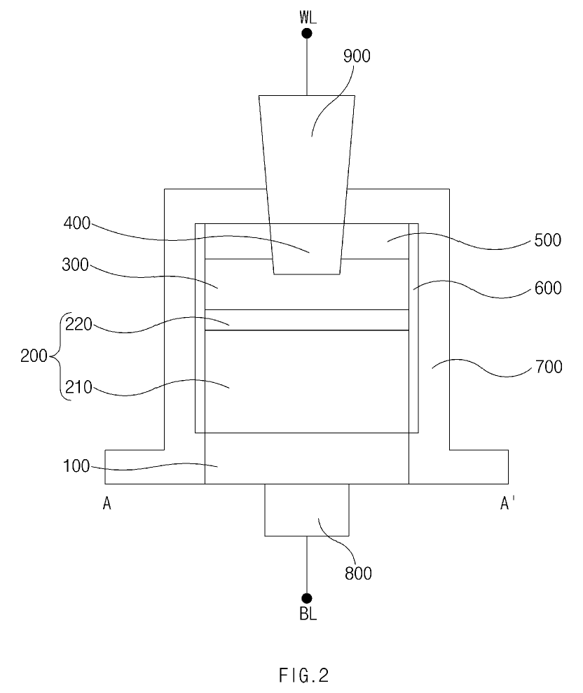

FIG. 2 is a cross-sectional view illustrating the resistive memory cell according to an embodiment of the present disclosure.

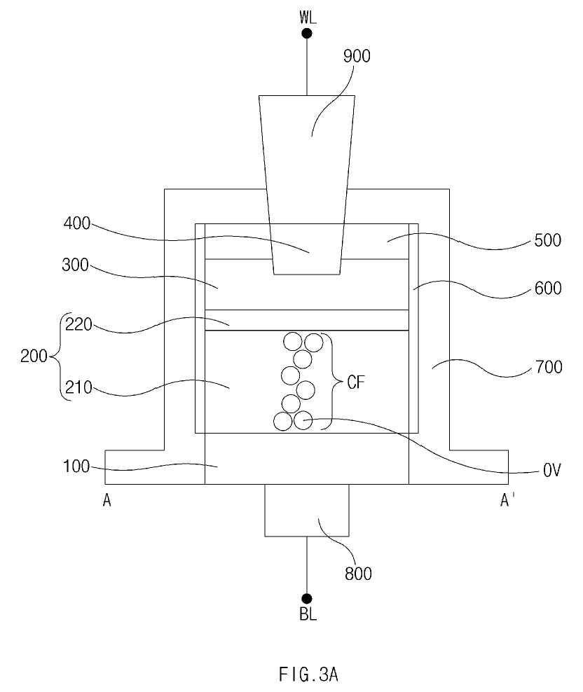

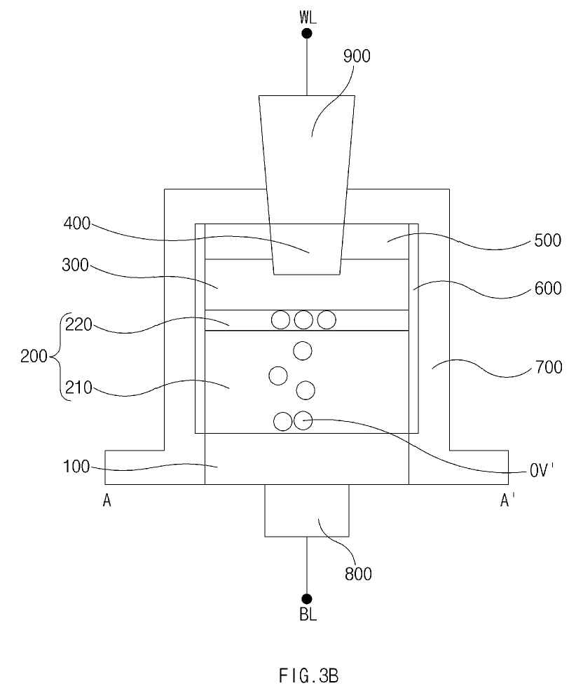

FIGS. 3A and 3B are cross-sectional views illustrating methods for operating the resistive memory cell according to an embodiment of the present disclosure.

FIG. 2 is a cross-sectional view illustrating the resistive memory cell (MC) of FIG. 1 taken along a first cutting line (A–A’) of FIG. 1.

FIGS. 3A and 3B are cross-sectional views illustrating respective methods of the switching operation of the resistive memory cell (MC) of FIG. 1 according to an embodiment of the present disclosure.

Referring to FIGS. 2, 3A, and 3B, a resistive memory cell (MC) may include: a first electrode 100; a variable resistance layer 200 disposed over the first electrode 100; a second electrode 300 disposed over the variable resistance layer 200; a first resistance layer 400 contacting the second electrode 300; a resistance isolation layer 500 disposed over the second electrode 300 and surrounding side surfaces of the first resistance layer 400; an insulation layer 600 surrounding side surfaces of the variable resistance layer 200, the second electrode 300, and the resistance isolation layer 500; a second resistance layer 700 surrounding side surfaces of the insulation layer 600 and contacting the first electrode 100; a first electrode contact 800 connected to the bitline (BL) and contacting the first electrode 100; and a second electrode contact 900 connected to the wordline (WL) and contacting the first resistance layer 400 and the second resistance layer 700.

In some embodiments, the first electrode 100 may serve as a lower electrode included in the resistive memory cell (MC). The first electrode 100 may include any one of a polysilicon layer, doped silicon, tungsten (W), gold (Au), platinum (Pt), palladium (Pd), rhodium (Rh), iridium (Ir), ruthenium (Ru), titanium (Ti), tantalum (Ta), molybdenum (Mo), chromium (Cr), vanadium (V), conductive nitrides of these metals, conductive silicides of these metals, and conductive oxides of these metals, or a combination thereof. Alternatively, the first electrode 100 may include a metal silicon nitride (e.g., WSiN) and the like.

The variable resistance layer 200 may include a metal oxide layer 210 and an oxygen vacancy reservoir layer 220.

The metal oxide layer 210 may include an oxide of a transition metal. For example, the metal oxide layer 210 may include an oxide of at least one of tantalum (Ta), scandium (Sc), yttrium (Y), titanium (Ti), zirconium (Zr), vanadium (V), chromium (Cr), niobium (Nb), osmium (Os), manganese (Mn), iron (Fe), nickel (Ni), copper (Cu), silver (Ag), zinc (Zn), hafnium (Hf), or tungsten (W).

The metal oxide layer 210 may have an electrically stoichiometric composition or an oxygen-deficient composition, so that oxygen vacancies (OV) can easily move within the metal oxide layer 210.

More specifically, the metal oxide layer 210 may include an oxide of a metal having a higher oxidation potential energy than that of the oxygen vacancy reservoir layer 220.

For example, when the oxygen vacancy reservoir layer 220 includes tantalum (Ta), the metal oxide layer 210 may include hafnium oxide (HfO₂), which has a higher oxidation potential than tantalum oxide (Ta₂O₅).

The oxygen vacancy reservoir layer 220 may include a metal or an oxide of the metal that can be variably oxidized or reduced depending on the direction of the electric field applied to the resistive memory cell (MC). In some embodiments, the oxygen vacancy reservoir layer 220 may include at least one of tantalum (Ta), titanium (Ti), zirconium (Zr), vanadium (V), tungsten (W), or ruthenium (Ru).

Oxygen vacancies (OV) may be dissolved within the oxygen vacancy reservoir layer 220 within a predetermined range. During the resistive switching operation of the resistive memory cell (MC), the oxygen vacancy reservoir layer 220 may exchange oxygen and oxygen vacancies (OV) with the metal oxide layer 210.

Referring to FIG. 3A, during a set operation of the resistive memory cell (MC), the oxygen vacancy reservoir layer 220 may supply oxygen vacancies (OV) to the metal oxide layer 210. The oxygen vacancies (OV) supplied to the metal oxide layer 210 may form a conductive filament (CF) within the metal oxide layer 210. The conductive filament (CF) facilitates charge transfer between the first electrode 100 and the second electrode 300. In other words, when the conductive filament (CF) is formed, the variable resistance layer 200 may switch to a low resistance state (LRS).

A specific state in which a conductive filament (CF) is formed in the metal oxide layer 210 by the set operation of the resistive memory cell (MC) may be referred to as an activation (or active) state of the resistive memory device. In this state, the resistance of the variable resistance layer 200 may be referred to as the activation resistance.

Referring to FIG. 3B, during a reset operation of the resistive memory cell (MC), the metal oxide layer 210 may supply oxygen vacancies (OV’) to the oxygen vacancy reservoir layer 220. As the oxygen vacancies (OV’) constituting the conductive filament (CF) (see FIG. 3A) are transferred to the oxygen vacancy reservoir layer 220, the conductive filament (CF) may collapse. When the conductive filament (CF) collapses, a charge transfer path between the first electrode 100 and the second electrode 300 is removed, and the variable resistance layer 200 may switch to a high resistance state (HRS).

A specific state in which the conductive filament (CF) is removed from the metal oxide layer 210 by the reset operation of the resistive memory cell (MC) may be referred to as a deactivation state of the resistive memory cell (MC). In this state, the resistance of the variable resistance layer 200 may be referred to as a deactivation (or inactive) resistance.

The second electrode 300 formed over the variable resistance layer 200 may contact the first resistance layer 400. The second electrode 300 may be a layer including a conductive material.

In some embodiments, the second electrode 300 may be a non-reactive electrode having weak reactivity with oxygen ions.

The non-reactive electrode may include a non-reactive metal having a weaker oxidizing power than the oxygen vacancy reservoir layer 220.

The second electrode 300 may include, for example, tungsten (W), gold (Au), platinum (Pt), palladium (Pd), rhodium (Rh), iridium (Ir), ruthenium (Ru), titanium (Ti), molybdenum (Mo), chromium (Cr), vanadium (V), conductive nitrides of these metals, conductive silicides of these metals, conductive oxides of these metals, or composite materials thereof. Alternatively, the second electrode 300 may include a metal silicon nitride, such as WSiN.

The first resistance layer 400 may be in contact with the second electrode 300, and may be a region including a material having a predetermined resistance value.

The equivalent resistance value of the first resistance layer 400 may be greater than the activation resistance value of the variable resistance layer and less than the resistance value of the second resistance layer 700.

The first resistance layer 400 may be disposed to penetrate the resistance isolation layer 500 and contact the second electrode 300. The first resistance layer 400 may extend into the second electrode 300 and be surrounded by the second electrode 300.

In some embodiments, as the contact area between the first resistance layer 400 and the second electrode 300 or the thickness of the first resistance layer 400 is changed, the resistance value of the first resistance layer 400 may be adjusted.

According to another embodiment, the first resistance layer 400 may include a plurality of layers, and a resistance value of each layer may be adjusted by adjusting the types of materials included in each layer.

According to an embodiment, the first resistance layer 400 may be formed of a metal, a conductive oxide, a conductive nitride, or a combination thereof.

The resistance isolation layer 500 may be a region formed over an upper portion of the second electrode 300. In some embodiments, the resistance isolation layer 500 may include an insulating material. For example, the resistance isolation layer 500 may include silicon nitride or the like.

The resistance isolation layer 500 may be disposed between the first resistance layer 400 and the second resistance layer 700.

The resistance isolation layer 500 may be a layer that defines a region in which the first electrode 100, the variable resistance layer 200, and the second electrode 300 are formed during the manufacturing process of the resistive memory cell (MC).

As the resistance isolation layer 500 is formed, process damage to the first electrode 100, the variable resistance layer 200, and the second electrode 300 located below the resistance isolation layer 500 during the manufacturing process of the resistive memory cell (MC) may be reduced.

The insulation layer 600 may be a region surrounding the side surfaces of the variable resistance layer 200, the second electrode 300, and the resistance isolation layer 500, and may include an insulating material. For example, the insulation layer 600 may include silicon oxide.

The insulation layer 600 may be disposed between the variable resistance layer 200 and the second resistance layer 700. In addition, the insulation layer 600 may be disposed between the second electrode 300 and the second resistance layer 700.

As the insulation layer 600 is formed, the variable resistance layer 200 and the second resistance layer 700 may be electrically isolated from each other, and the second electrode 300 and the second resistance layer 700 may also be electrically isolated from each other.

The second resistance layer 700 may be a region surrounding the insulation layer 600. The second resistance layer 700 may include an insulation layer (not illustrated) doped with a conductive material. For example, the second resistance layer 700 may include silicon nitride doped with titanium. The material doped into the second resistance layer 700 may further include, for example, tellurium (Te). The equivalent resistance value of the second resistance layer 700 may vary depending on the amount of metal ions doped with which the second resistance layer 700 is doped.

For example, the equivalent resistance value of the second resistance layer 700 may be less than the deactivation (or inactive) resistance value of the variable resistance layer 200 and higher than the equivalent resistance value of the first resistance layer 400.

The second resistance layer 700 may be included in each of the adjacent resistive memory cells (MC). The second resistance layer 700 may serve as a spacer region that separates the variable resistance layer 200 from the variable resistance layers 200 of another adjacent resistive memory cell (MC). An insulation layer may be disposed between adjacent second resistance layers 700.

The first electrode contact 800 may be a region that is in contact with the first electrode 100, and may include a conductive material. For example, the first electrode contact 800 may be formed of a metal, a conductive oxide, a conductive nitride, or a combination thereof.

The first electrode contact 800 may be a region that connects the first electrode 100 to the bitline (BL).

The second electrode contact 900 may be a region that is in contact with the first resistance layer 400 and the second resistance layer 700, and may include a conductive material. For example, the second electrode contact 900 may be formed of a metal, a conductive oxide, a conductive nitride, or a combination thereof.

The second electrode contact 900 may be a region that connects the first resistance layer 400 and the second resistance layer 700 to the wordline (WL).

As described above with reference to FIG. 2, the read and write operations of the resistive memory cell (MC) may be performed according to the activation states of the wordline (WL) and the bitline (BL).

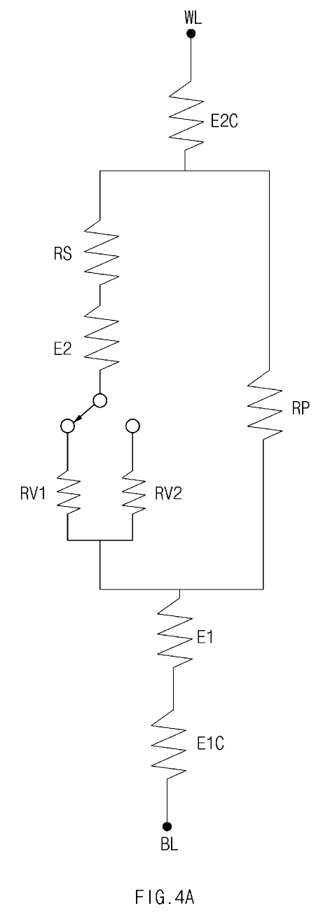

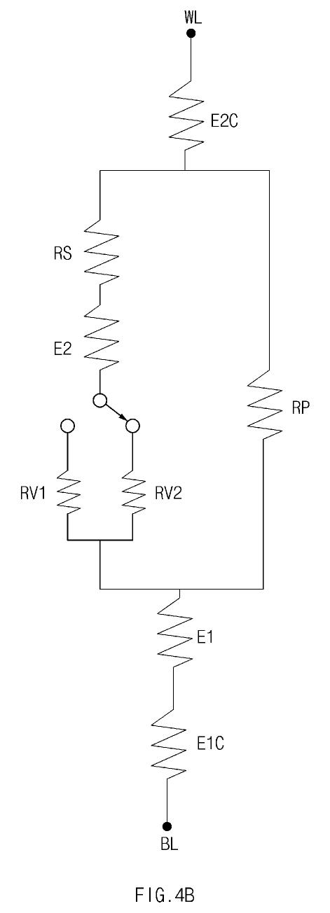

FIGS. 4A and 4B are equivalent circuit diagrams illustrating the resistive memory cell (MC) according to an embodiment of the present disclosure. In the following description, the result of comparison between the activation resistance and the deactivation resistance of the resistive memory cell (MC) according to an embodiment of the present disclosure will hereinafter be described with reference to FIGS. 4A and 4B.

FIG. 4A is an equivalent circuit diagram illustrating the resistive memory cell (MC) operating in the activation state. Referring to FIG. 4A, an equivalent resistance (E1C) of a first electrode contact may be connected in series to an equivalent resistance (E1) of a first electrode. The equivalent resistance (E1) of the first electrode may be connected to the variable resistance layer depicted as a switching element, and may also be connected to the second resistance layer (RP).

The variable resistance layer 200 may be represented as a switching element. When the variable resistance layer 200 is in the activation state, the variable resistance layer 200 may be replaced with an activation resistor (RV1).

The variable resistance layer 200 may be connected in series to the equivalent resistance (E2) of the second electrode. In addition, the equivalent resistance (E2) of the second electrode may be connected in series to the first resistance layer (RS).

The first resistance layer (RS) and the second resistance layer (RP) may be connected to the equivalent resistance (E2C) of the second electrode contact.

FIG. 4B is an equivalent circuit diagram illustrating the resistive memory cell (MC) operating in the deactivation state. Referring to FIG. 4B, the connection relationships among the other resistors are the same as those in FIG. 4A, except that the variable resistance layer 200 is replaced with a deactivation resistor (RV2).

When the resistive memory cell (MC) is in the activation state, a conductive filament (CF) may be formed within the variable resistance layer 200. As the conductive filament (CF) is formed, the variable resistance layer 200 may enter a low-resistance state.

When the resistive memory cell (MC) is in the deactivation state, the conductive filament (CF) within the variable resistance layer 200 may be removed. As the conductive filament (CF) is removed, the variable resistance layer 200 may enter a high-resistance state.

Accordingly, the resistance value of the activation resistance (RV1) may be less than the resistance value of the deactivation resistance (RV2).

The resistive memory cell (MC) according to an embodiment of the present disclosure may exhibit minimal variation in activation and/or deactivation resistances even when the operating characteristics of the variable resistance layer 200 are deteriorated, thereby ensuring uniformity between switching cycles and improving the reliability of the switching mechanism.

In some embodiments, since the first electrode contact 800, the first electrode 100, the second electrode contact 900, and the second electrode 300 are conductors, the equivalent resistance (E1C) of the first electrode contact, the equivalent resistance (E1) of the first electrode, the equivalent resistance (E2C) of the second electrode contact, and the equivalent resistance (E2) of the second electrode may be regarded as being equivalent to the resistance of conductive lines, and may be neglected in equivalent resistance calculations.

In addition, as a conductive filament (CF) is formed within the variable resistance layer 200, the resistance value of the activation resistor (RV1) may also be regarded as being equivalent to that of a conductor, and may be neglected in equivalent resistance calculations.

Accordingly, the equivalent resistance of the resistive memory cell (MC) operating in the activation state may be considered as parallel connection between the first resistance layer (RS) and the second resistance layer (RP).

When the resistive memory cell (MC) is in the activation state and the resistance of the first resistance layer (RS) is much smaller than that of the second resistance layer (RP), the activation resistance value of the resistive memory cell (MC) may be regarded as being equivalent to the resistance value of the first resistance layer (RS).

When the resistive memory cell (MC) is in the deactivation state, the conductive filament (CF) within the variable resistance layer 200 is removed, and the variable resistance layer 200 may operate as an insulator (or a nonconductor).

Accordingly, a resistance value of the deactivation resistor (RV2) may be much greater than that of the first resistance layer (RS) and the second resistance layer (RP). When the resistive memory cell (MC) is in the deactivation state, a resistance value of the deactivation resistor (RV2) may be significantly greater than that of the first resistance layer (RS), and a resistance value of the series-connected first resistance layer (RS) may be negligible.

Accordingly, the equivalent resistance of the resistive memory cell (MC) in the deactivation state may be considered as a parallel connection between the deactivation resistor (RV2) and the second resistance layer (RP).

When a resistance value of the deactivation resistor (RV2) is much greater than the resistance value of the second resistance layer (RP), the deactivation resistance value of the resistive memory cell (MC) may be regarded as being equivalent to the resistance value of the second resistance layer (RP).

The resistive memory cell (MC) according to an embodiment of the present disclosure may include a first resistance layer (RS) and a second resistance layer (RP), and a resistance value of the first resistance layer (RS) and a resistance value of the second resistance layer (RP) may be adjusted. As a result, during the activation state, the resistive memory cell (MC) may have a resistance value of the first resistance layer (RS), and during the deactivation state, the resistive memory cell (MC) may have a resistance value of the second resistance layer (RP).

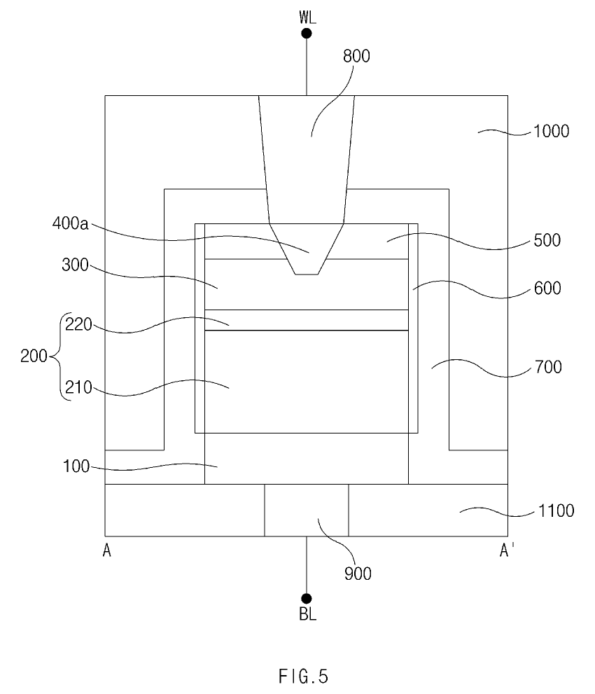

FIG. 5 is a cross-sectional view illustrating a resistive memory device according to another embodiment of the present disclosure.

Referring to FIG. 5, the remaining structures except for the configuration of the first resistance layer 400a are substantially the same as those of FIG. 2, as such redundant description thereof will herein be omitted for brevity. The embodiment of FIG. 5 will focus on the structure of the first resistance layer 400a for convenience of description.

The first resistance layer 400a shown in FIG. 5 may have a structure in which a lower width is smaller than an upper width between the wordline WL and the bitline BL of the resistive memory device.

The first resistance layer 400a shown in FIG. 5 may have a smaller contact area between the first resistance layer 400a and the second electrode 300 compared to the first resistance layer 400 (see FIG. 2). In addition, as the cross-sectional area of the first resistance layer 400a is reduced, the resistance value of the first resistance layer 400a may increase.

In some embodiments, the shape of the first resistance layer 400a may be changed by adjusting the etch selectivity between the resistance isolation layer 500 and the second electrode 300. The etch selectivity between the resistance isolation layer 500 and the second electrode 300 may be adjusted either by changing the composition of the material layer included in the resistance isolation layer 500 or by changing the etching gas.

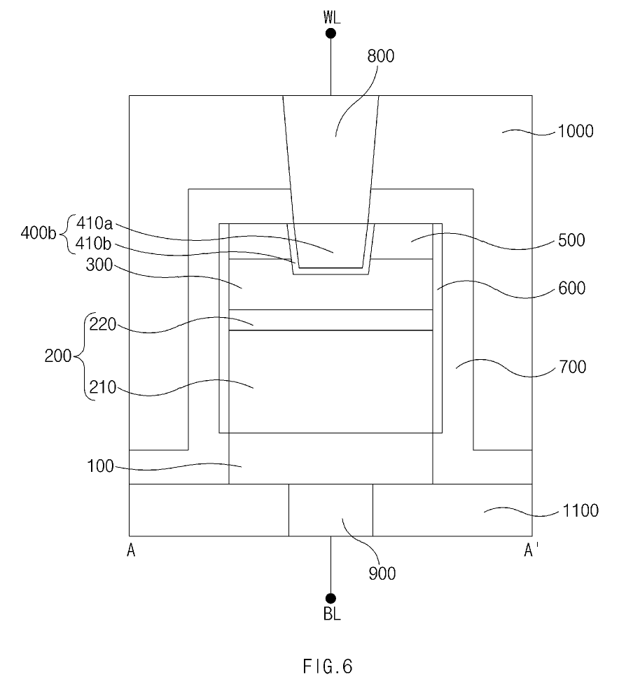

FIG. 6 is a cross-sectional view illustrating a resistive memory device according to still another embodiment of the present disclosure.

Referring to FIG. 6, the remaining structures except for the configuration of the first resistance layer 400b are substantially the same as those of FIG. 2, as such redundant description thereof will herein be omitted for brevity. The embodiment of FIG. 6 will focus on the structure of the first resistance layer 400b for convenience of description.

The first resistance layer 400b shown in FIG. 6 may include a lower resistance layer 410b and an upper resistance layer 410a.

Although not shown in FIG. 6, in other embodiments, the first resistance layer 400b may include more layers in addition to the two layers.

The lower resistance layer 410b and the upper resistance layer 410a may include materials having different resistivities.

For example, the lower resistance layer 410b may include silicon oxide having a high resistivity, and the upper resistance layer 410a may include a conductive material such as polysilicon.

As the first resistance layer 400b includes multiple layers and the resistivity values and shapes of the multiple layers are adjusted, the resistance value of the first resistance layer 400b may also be adjusted.

In some embodiments, the first resistance layer 400b having an adjusted resistance value may be formed by etching the resistance isolation layer 500 and the second electrode 300 and then forming multiple layers in the etched region.

For example, the resistance value of the first resistance layer 400b may be adjusted by forming a silicon oxide layer on the etched resistance isolation layer 500 and the second electrode 300 using an ultra-low temperature oxide (ULTO) process or the like.

As is apparent from the above description, the resistive memory cell (MC) according to the embodiments of the present disclosure includes a series resistor and a parallel resistor, and adjusts resistance values of the series and parallel resistors, so that uniformity between the activation resistance and deactivation resistance during switching cycles can be maintained.

The resistive memory cell (MC) according to the embodiments of the present disclosure can prevent durability degradation caused by repeated switching cycles by adjusting the resistance values of the series and parallel resistors, thereby improving the reliability of the switching mechanism.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A resistive memory device comprising:
a variable resistance layer disposed over an upper portion of a first electrode;
a second electrode disposed over an upper portion of the variable resistance layer;
a first resistance layer disposed to contact the second electrode;
an insulation layer disposed to surround side surfaces of the variable resistance layer and the second electrode; and
a second resistance layer disposed to surround the insulation layer and to contact the first electrode.

2. The resistive memory device according to claim 1, further comprising:
a second electrode contact disposed to commonly contact the first resistance layer and the second resistance layer.

3. The resistive memory device according to claim 1, wherein:
the variable resistance layer includes a conductive filament comprising oxygen vacancies.

4. The resistive memory device according to claim 1, wherein:
the variable resistance layer includes a metal oxide layer and an oxygen vacancy reservoir layer.

5. The resistive memory device according to claim 4, wherein:
the metal oxide layer includes an oxide of at least one of tantalum (Ta), scandium (Sc), yttrium (Y), titanium (Ti), zirconium (Zr), vanadium (V), chromium (Cr), niobium (Nb), osmium (Os), manganese (Mn), iron (Fe), nickel (Ni), copper (Cu), silver (Ag), zinc (Zn), hafnium (Hf), or tungsten (W).

6. The resistive memory device according to claim 4, wherein:
the metal oxide layer includes a metal oxide having a higher oxidation potential energy than that of the oxygen vacancy reservoir layer.

7. The resistive memory device according to claim 4, wherein:
the oxygen vacancy reservoir layer includes a metal or an oxide of the metal that is at least one of tantalum (Ta), titanium (Ti), zirconium (Zr), vanadium (V), tungsten (W), or ruthenium (Ru).

8. The resistive memory device according to claim 1, wherein:
the first electrode and the second electrode include a non-reactive conductive material.

9. The resistive memory device according to claim 1, wherein:
the variable resistance layer has an activation resistance value when a conductive filament is present and a deactivation resistance value when the conductive filament is not present or electrically disconnected.

10. The resistive memory device according to claim 9, wherein:
a resistance value of the first resistance layer is greater than the activation resistance value of the variable resistance layer and less than the deactivation resistance value of the variable resistance layer.

11. The resistive memory device according to claim 1, wherein:
a resistance value of the first resistance layer is less than a resistance value of the second resistance layer.

12. The resistive memory device according to claim 1, further comprising:
a resistance isolation layer disposed over an upper portion of the second electrode and surrounding side surfaces of the first resistance layer.

13. The resistive memory device according to claim 1, further comprising:
a second electrode contact disposed to contact the first resistance layer,
wherein the second resistance layer is in contact with side surfaces of the second electrode contact.

14. The resistive memory device according to claim 1, further comprising:
a first electrode contact disposed to contact the first electrode;
a second electrode contact disposed to contact the first resistance layer;
at least one bitline contacting the first electrode contact and extending in a first direction; and
at least one wordline contacting the second electrode contact and extending in a second direction.

15. The resistive memory device according to claim 1, wherein:
the first resistance layer includes a plurality of material layers having different resistance values.

16. The resistive memory device according to claim 1, wherein:
the first resistance layer includes an area of one surface contacting the second electrode that is smaller in width than an area of another surface facing or opposite to the area of the one surface.

17. A resistive memory device comprising:
a first electrode connected to a first electrode contact;
a variable resistance layer connected in series to the first electrode;
a second electrode connected in series to the variable resistance layer;
a first resistance layer connected in series to the second electrode;
a second resistance layer connected to the first electrode, and connected in parallel to the variable resistance layer, the second electrode, and the first resistance layer; and
a second electrode contact connected to the first resistance layer and the second resistance layer.

18. The resistive memory device according to claim 17, wherein:
the first electrode contact is connected to a bitline; and
the second electrode contact is connected to a wordline.

19. The resistive memory device according to claim 17, further comprising:
an insulation layer disposed between the second resistance layer and each of the variable resistance layer, the second electrode and the first resistance layer,
wherein the insulation layer electrically isolates the second resistance layer from each of the variable resistance layer, the second electrode and the first resistance layer.
